(19) United States
(12) Patent Application Publication
(10) Pub. No.: US 2004/0257764 A1
(43) Pub. Date: Dec. 23, 2004

(54) Bidirectional indraft type centrifugal fan and cooling apparatus for computer

(76) Inventor: Sung-Wook Jang, Seoul (KR)

Correspondence Address: HOLLAND & KNIGHT LLP, 633 WEST FIFTH STREET, TWENTY-FIRST FLOOR, LOS ANGELES, CA, 90071-2040, US

(21) Appl. No.: 10/495,376

(22) PCT Filed: Nov. 12, 2002
(86) PCT No.: PCT/KR02/02116

(30) Foreign Application Priority Data
Nov. 13, 2001 (KR) 70359/2001

(51) Int. Cl. H05K 5/00

(52) U.S. Cl. 361/687

(57) ABSTRACT

A double suction centrifugal fan capable of bidirectionally sucking fluid and a cooling apparatus for a computer using the same. In the centrifugal fan and the cooling apparatus, a disk is provided between blades and a hub so that fluid is sucked to both faces of the disk and then discharged toward the blades. That is, interference between sucked fluid is minimized to restrain creation of turbulence flow, thereby reducing noise and improving efficiency. Also inner ends of the blades of the centrifugal fan are arranged in an inner portion of the disk to relatively shorten the chord length of the blades, resultantly reducing tonal noise owing to BPF and thermal deformation of the blades.

### TECHNICAL FIELD

The present invention relates to a cooling apparatus for a computer, and more particularly, to a double suction centrifugal fan capable of bidirectionally sucking fluid and a cooling apparatus for a computer using the same.

### BACKGROUND ART

A conventional cooling apparatus generally uses an axial flow fan. However, a notebook computer preferably uses a centrifugal fan having a higher static pressure than the axial flow fan since it has a very high degree of integration and a large pneumatic resistance of fluid.

The centrifugal fan is generally classified into a single suction fan which sucks fluid in one direction and a double suction fan which sucks fluid in both directions according to suction type. A conventional single suction centrifugal fan will be described in reference to FIG. 1.

As shown in FIG. 1, a centrifugal fan 10 has a circular backing plate 11, a hub 13 on a central portion of the backing plate 11 and a plurality of blades 15 which are radially arranged from the hub 13 in a periphery of the backing plate 11. A rim-shaped rib 17 is coupled to tops of the blades 15 to reinforce the strength of the blades 15. The hub 13 is coupled with a shaft 19 of an external motor so that the centrifugal fan 10 is rotated via rotation of the shaft 19.

Since the conventional centrifugal fan 10 configured as above sucks fluid only in one direction, when applied to the cooling apparatus for a computer, the cooling efficiency thereof is disadvantageously degraded in respect to the double suction centrifugal fan owing to spatial restriction.

Further, the motor for rotating the centrifugal fan 10 is additionally installed outside the centrifugal fan 10 and thus occupies a large space. As a result, there is a disadvantage in that the conventional single suction centrifugal fan is rarely applied in an article having a high integrity of components such as the notebook computer.

FIG. 2A shows a double suction centrifugal fan which is proposed to solve the above drawbacks.

As shown in FIG. 2B, a centrifugal fan 20 includes a hub 21 on which a motor 30 (FIG. 2B) is internally mounted and a plurality of blades 23 radially arranged in a periphery of the hub 21.

The centrifugal fan 20 is installed in a frame 40 having openings in a top and a lateral portion thereof. A plurality of cooling fins 43 are installed adjacent to the lateral opening of the frame 40, and a cover 47 is put over the upper opening of the frame 40. The frame 40 has an inlet 40a and the cover 47 has an inlet 47a so that the inlets 40a and 47a outwardly expose inner ends and central portions of the blades 23 and the frame 40 and the cover 47 enclose outer ends of the blades 23.

As a result, as the centrifugal fan 20 is rotated via driving force of the motor, fluid is sucked into the inlet 40a of the frame 40 and the inlet 47a of the cover 47 and discharged toward the cooling fins 43 to cool the cooling fins 43.

The conventional centrifugal fan 20 as set forth above, however, has drawbacks in that fluid sucked through the inner ends of the blades 23 interferes with fluid sucked through the central portions of the blades 23 to create inlet turbulence thereby generating heavy noise and deteriorating efficiency.

Further, since the blades have a long chord length, tonal noise disadvantageously increases owing to Blade-Passing Frequency (BPF), i.e., a unique frequency of noise occurring in a rotating structure having blades.

Thermal deformation readily occurs according to application conditions owing to the long chord length.

Furthermore, although the centrifugal fan having the above configuration is applicable with small number of blades, when the centrifugal fan has a large number of blades, it is structurally difficult to use the above centrifugal fan.

### DISCLOSURE OF THE INVENTION

The present invention has been made to solve the foregoing problems and it is therefore an object of the invention to provide a double suction centrifugal fan capable of minimizing turbulence flow owing to interference between fluid sucked in both directions in order to reduce noise as well as improve efficiency, and a cooling apparatus for a computer using the same.

It is another object of the invention to provide a double suction centrifugal fan capable of reducing the chord length of blades in order to further reduce noise as well as prevent deformation of the blades, and a cooling apparatus for a computer using the same.

It is yet another object of the invention to provide a double suction centrifugal fan capable of being used without restriction in number of blades and a cooling apparatus for a computer using the same.

According to an aspect of the invention for realizing the above objects, a double suction centrifugal fan comprises: a cylindrical hub; a single disk arranged in both surfaces of the hub; and a plurality of blades regularly arranged in the disk.

According to another aspect of the invention for realizing the above objects, a cooling apparatus for a computer comprises: a frame installed within a computer main frame and having openings in a top and a lateral portion and a rim-shaped frame inlet in an underside; a cover coupled to the upper opening of the frame and having a cover inlet which is concentric with the frame inlet and has a diameter similar to a diameter of the frame inlet; a plurality of cooling fins arranged in the lateral opening of the frame; a centrifugal fan including a cylindrical hub having an opening in one face, a rim-shaped disk arranged in an outer periphery of the hub and a plurality of blades regularly arranged in the disk and for sucking fluid into the frame inlet and the cover inlet and discharging fluid toward the cooling fins; and a motor for rotating the centrifugal fan.

### BRIEF DESCRIPTION OF THE DRAWINGS

FIG. 1 is a perspective view of a conventional single suction centrifugal fan;

FIG. 2A is a perspective view of a conventional double suction centrifugal fan;

FIG. 2B is a sectional view illustrating application of the centrifugal fan of FIG. 2A;

FIG. 3A is an exploded perspective view of a centrifugal fan and a cooling apparatus according to a first embodiment of the invention;

FIG. 3B is an assembled sectional view illustrating application of the centrifugal fan of FIG. 3A;

FIG. 4 is a graph illustrating OSPL of the centrifugal fan in FIG. 3A compared with a conventional centrifugal fan;

FIG. 5A is graphs illustrating the sound pressure level according to frequency of the centrifugal fan according to the first embodiment of the invention compared with that of the conventional centrifugal fan;

FIG. 5B illustrates the graphs of FIG. 5A in one graph for the purpose of easy comparison;

FIG. 6 is a graph illustrating an overall P-Q performance curve of the centrifugal fan according to the first embodiment of the invention compared with that of the centrifugal fan of the prior art;

FIG. 7A is an exploded perspective view of a centrifugal fan according to a second embodiment of the invention;

FIG. 7B is an assembled sectional view illustrating application of the centrifugal fan in FIG. 7A;

FIG. 8A through 8C are perspective views of centrifugal fans according to third through fifth embodiments of the invention; and

FIG. 9A through 9C are perspective views of centrifugal fans according to sixth through eighth embodiments of the invention.

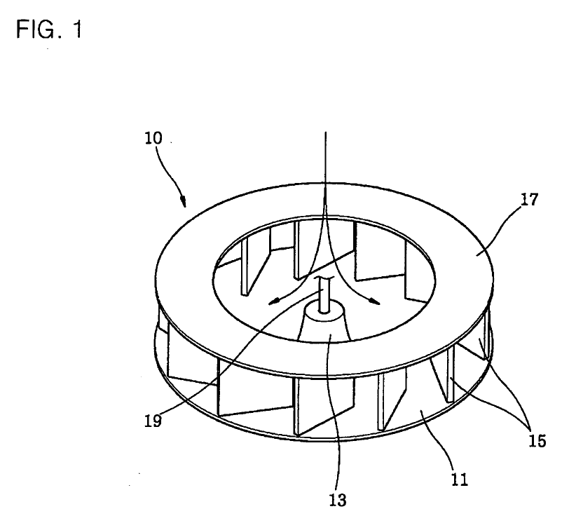

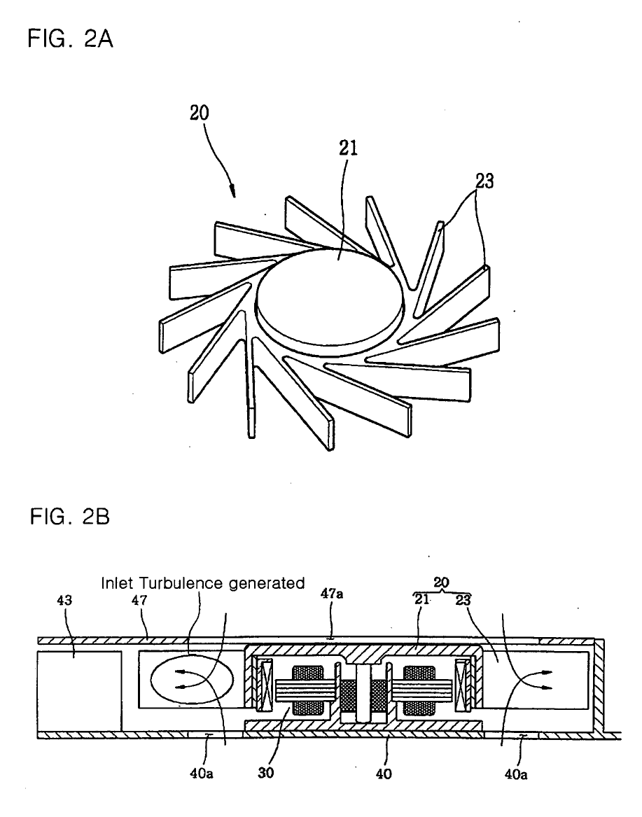

### BEST MODE FOR CARRYING OUT THE INVENTION

The following detailed description will present preferred embodiments of a centrifugal fan and a cooling apparatus for a computer according to the invention in reference to the accompanying drawings.

### FIRST EMBODIMENT

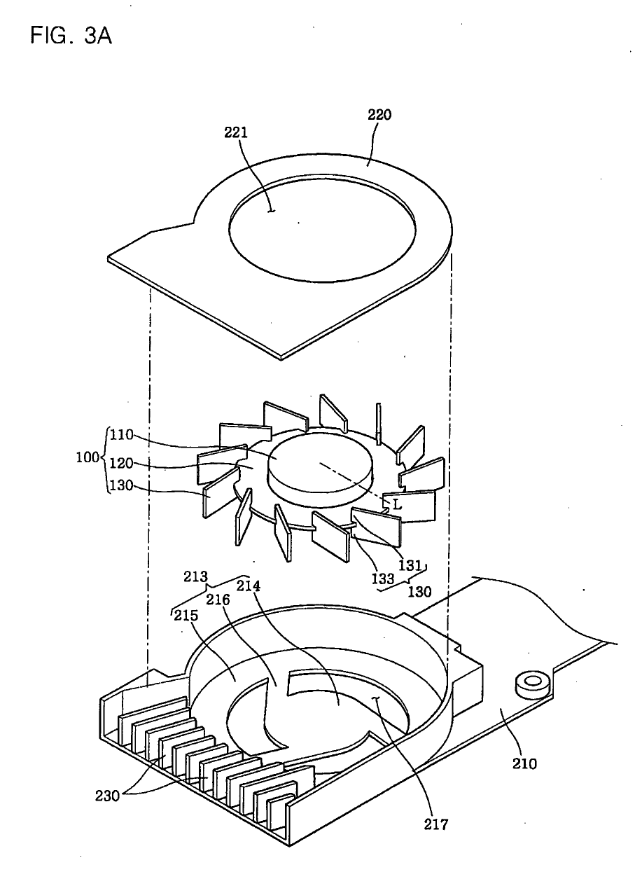

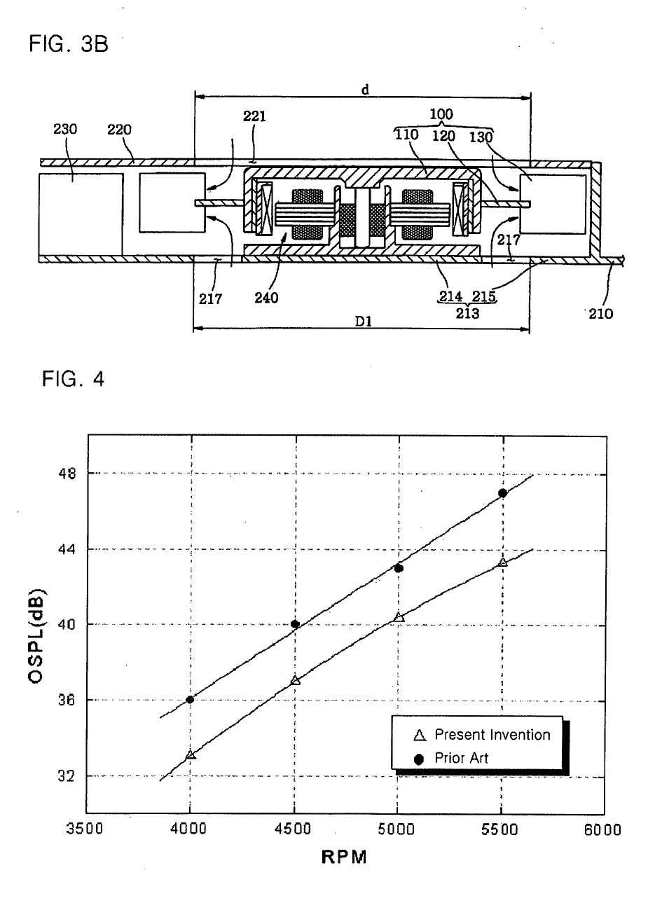

FIG. 3A is an exploded perspective view of a centrifugal fan and a cooling apparatus according to a first embodiment of the invention, which will be described as follows.

As shown in FIG. 3A, a centrifugal fan 100 includes a hub 110, a disk 120 and a plurality of blades 130. The hub 110 is shaped as a hollow cylinder having an opening at one end and has a motor 240 (FIG. 3B) therein. The disk 120 is shaped as a rim with its inner periphery coupled to an outer periphery of the hub 110. The blades 130 are arranged in a periphery of the disk 120 radially about the center of the hub 110, and inclined at a certain angle about a line L extended from a radius of the disk 120.

Describing the above in more detail, the blades 130 are arranged to face to the outside from the inside of the disk 120, and have one ends or inner ends integrally arranged between inner and outer peripheries of the disk 120, and the other ends or outer ends extended beyond the disk 120. The blades 130 have regions 131 and 133 projected upward and downward respectively from the disk 120, in which the upwardly projected regions 131 are shaped substantially identical with the downwardly projected regions 133. That is, the blades 130 are partially inserted into the disk 120 so that the regions 131 of the blades 130 upwardly projected from the disk 120 are configured identical with the regions 133 of the blades 130 downwardly projected from the disk 120.

The inner ends of the blades 130 are integrally formed between the inner and outer periphery of the disk 120 as above so as to reinforce the strength of coupling portions between the disk 120 and the blades 130. The number of the blades 130 is preferably 12 to 24 (the reason will be described later in the specification).

Application of the above configured centrifugal fan 100 to a notebook computer will be described in reference to FIGS. 3A and 3B.

FIG. 3B is an assembled sectional view illustrating application of the centrifugal fan of FIG. 3A.

As shown in FIG. 3B, a frame 210 is mounted on a central processing unit (not shown) built in a computer main frame (not shown). The frame 210 has openings in a top and a lateral portion thereof and an inlet 217 in an underside 213 thereof. That is, the underside 213 includes a central portion 214 and an outer portion 215 with an inner periphery of the outer portion 215 being spaced apart from an outer periphery of the central portion 214 by a certain interval to define the inlet 217. The central portion 214 and the outer portion 215 are connected to each other via connecting portions 216 (FIG. 3A).

A cover 220 is coupled to the upper opening of the frame 210, and a plurality of cooling fins 230 are installed in the lateral opening. The cover 220 has an inlet 221 which is concentric with the inlet 217 of the frame 210. The inlet 221 of the cover 220 also has a diameter d identical with a diameter D1 of the inlet 217 of the frame 210.

A centrifugal fan 100 is installed in the frame 210. Describing this in detail, the hub 110 having the motor 240 built therein for rotating the centrifugal fan 100 is supported on the central portion 214 of the underside 214 of the frame 210. The disk 120 is opposed to both the inlet 217 of the frame 210 and the inlet 221 of the cover 220. The outer periphery of the disk 120 is positioned over the outer portion 215 of the frame 210 beyond the inlet 217 of the frame 210, and preferably over the outer portion 215 of the frame 210 connected to an outside of the inlet 217 of the frame 210. Then, the inner ends and central portions of the blades 130 are outwardly exposed through the inlet 217 of the frame 210 and the inlet 221 of the cover 220, whereas the outer ends of the blades 130 are covered with the frame 210 and the cover 220.

In the centrifugal fan 100 according to the first embodiment of the invention, the number of the blades is 12 to 24 as set forth above. A fan having 12 through 24 blades is generally called a turbofan, and since a double suction turbo fan has a relatively long chord length of blades functioning as rotating bodies to impart energy to liquid, the outer ends of the blades are covered with the frame 210 and the cover 220.

As a result, fluid is sucked through both the inlets 217 and 221 of the frame 210 and the cover 220 via the centrifugal fan 100 and then flows toward the blades 130 under the guidance of both faces of the disk 120, thereby solving interference between fluid. This resultantly restricts creation of turbulence flow.

Also the inner ends of the blades 130 are provided integral with the faces of the disk 120 so that the chord length of the blades is reduced compared to the conventional blades. As a result, tonal noise owing to BPF is decreased and thermal deformation rarely takes place.

Effects of noise reduction and performance improvement according to the first embodiment of the invention will be more apparent in reference to FIGS. 4 through 6.

FIG. 4 is a graph illustrating Overall Sound Pressure Level (OSPL) of the centrifugal fan in FIG. 3A compared with a conventional centrifugal fan.

Referring to FIG. 4, the centrifugal fan according to the first embodiment of the invention has an effect of reducing OSPL for about 3 dB compared to the conventional centrifugal fan.

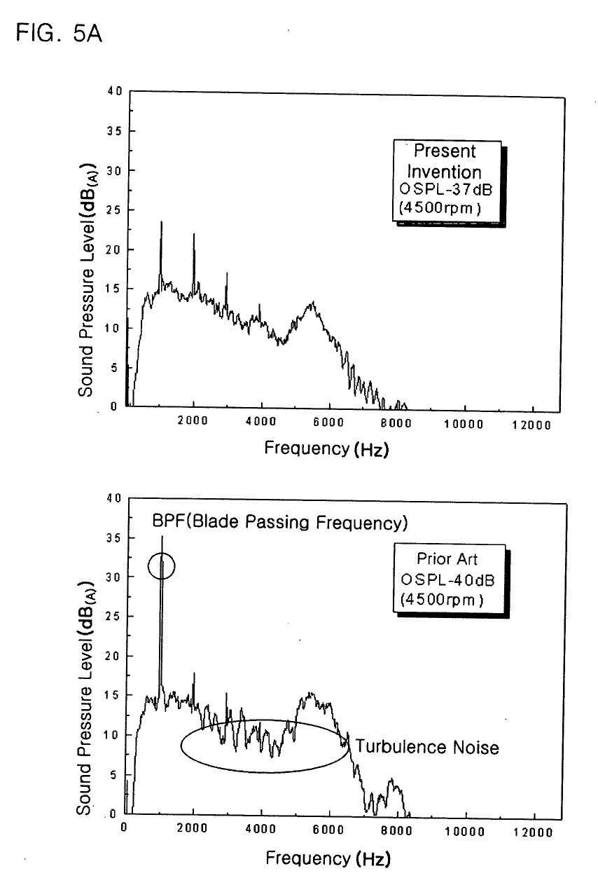

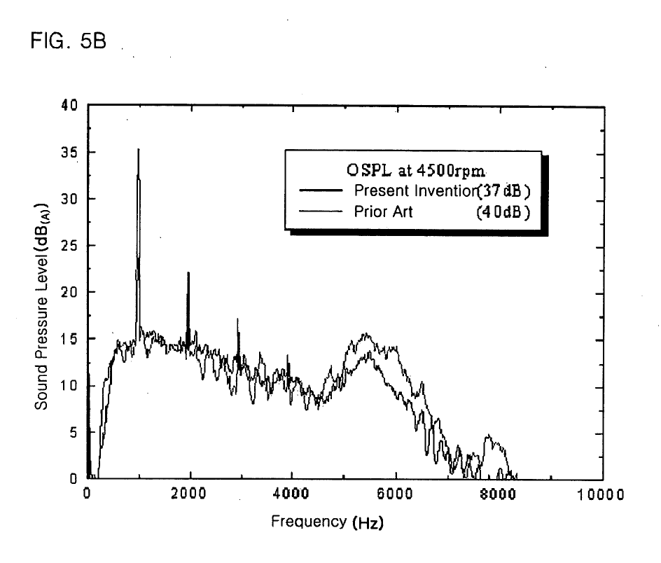

FIG. 5A is a graph illustrating the sound pressure level according to frequency of the centrifugal fan according to the first embodiment of the invention compared with that of the conventional centrifugal fan, and FIG. 5B illustrates the graph of the centrifugal fan of the invention overlapped with that of the conventional centrifugal fan in one drawing.

In particular, FIGS. 5A and 5B illustrate the sound pressure level according to frequency at a point of 4500 RPM (i.e., at a point where OSPL is 37 dB in the invention and 40 dB in the prior art) in the OSPL graph of FIG. 4.

Referring to FIGS. 5A and 5B, since the sound pressure level of the centrifugal fan of the invention is shown as a curve smoother than that of the conventional centrifugal fan, tonal noise owing to BPF is remarkably reduced and turbulence noise is also reduced by a large amount. That is, the inner ends of the centrifugal fan of the invention are formed in an inner portion of the disk to shorten the chord length of the blades thereby reducing tonal noise owing to BPF.

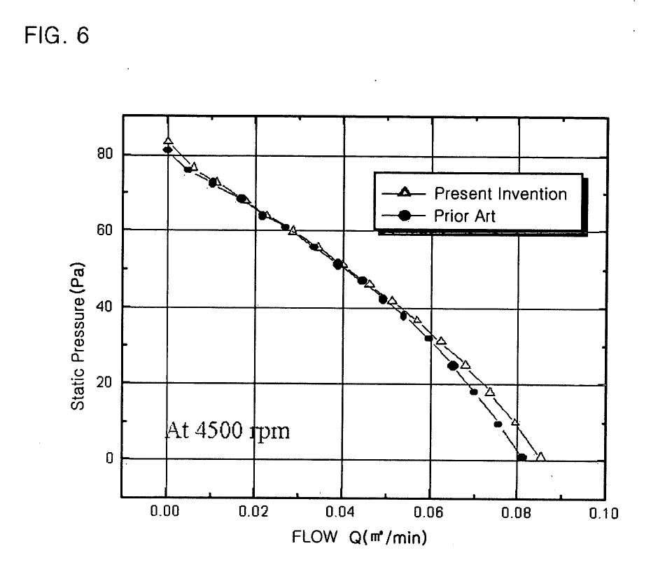

FIG. 6 is a graph illustrating an overall P-Q performance curve of the centrifugal fan according to the first embodiment of the invention compared with that of the centrifugal fan of the prior art.

Referring to FIG. 6, the inclination of the graph is substantially coincident, and it can be understood from the graph that the centrifugal fan of the invention has similar or better P-Q performance in respect to the conventional centrifugal fan.

### SECOND EMBODIMENT

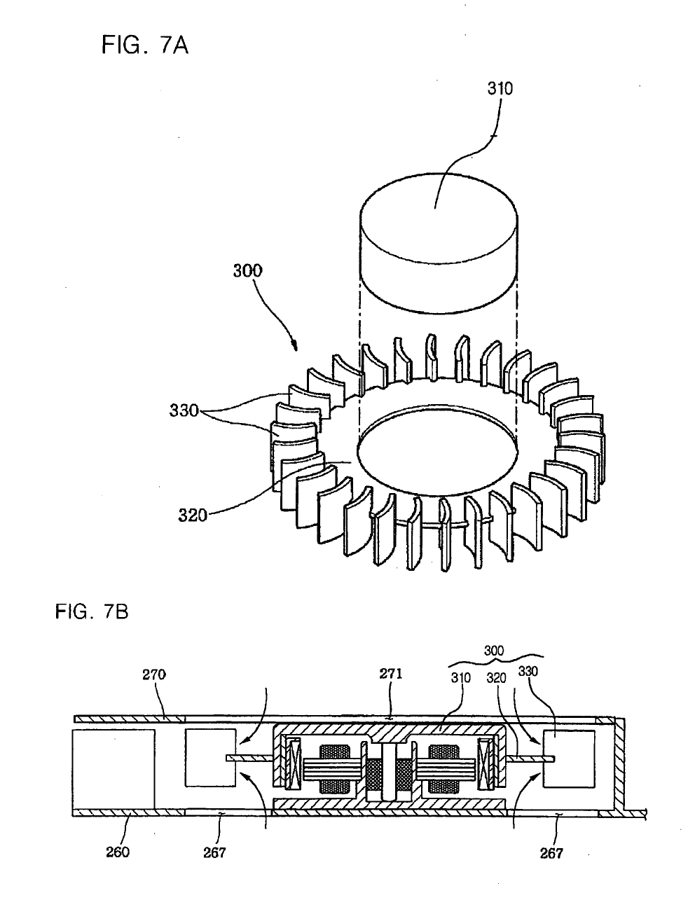

FIG. 7A is an exploded perspective view of a centrifugal fan according to a second embodiment of the invention, and FIG. 7B is an assembled sectional view illustrating application of the centrifugal fan in FIG. 7A.

This embodiment will be described about differences thereof in comparison with the first embodiment, in which the number of the blades 330 of a centrifugal fan 300 is at least 25 and arranged together with a disk 320 between inner and outer peripheries of inlets 267 and 271 of a frame 260 and a cover 270. A multiblade fan generally means a fan in which blades have an exit angle of about 90 deg. or more and the number of the blades is 36 to 64. Since a double suction multiblade fan has a relatively short chord length of blades which function as rotating bodies to impart energy to fluid, outer ends of the blades 330 may be selectively covered with the frame 260 and the cover 270.

FIG. 7B shows that the disk 320 and the blades 330 are outwardly exposed through the inlets 267 and 271 of the frame 260 and the cover 270.

### THIRD THROUGH FIFTH EMBODIMENTS

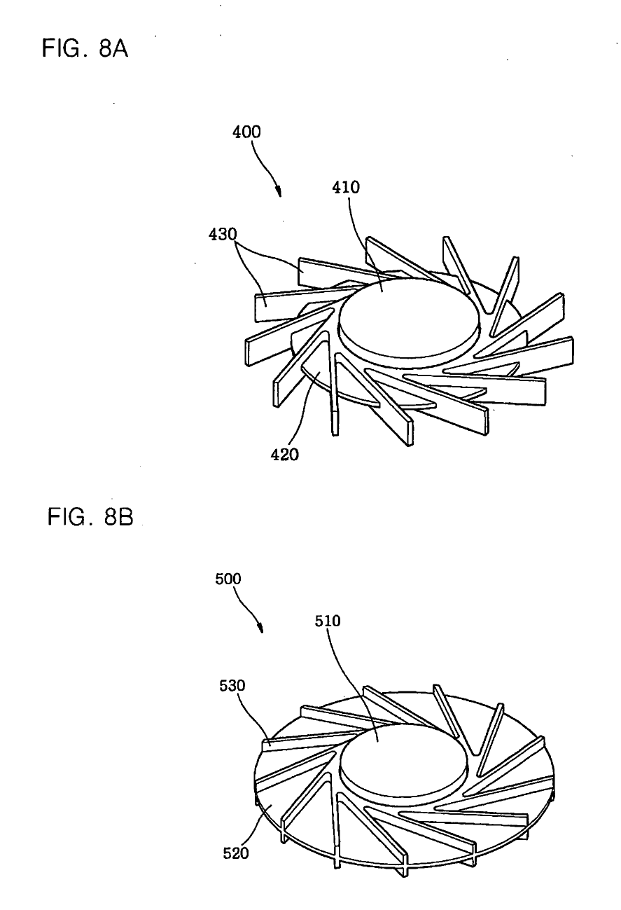

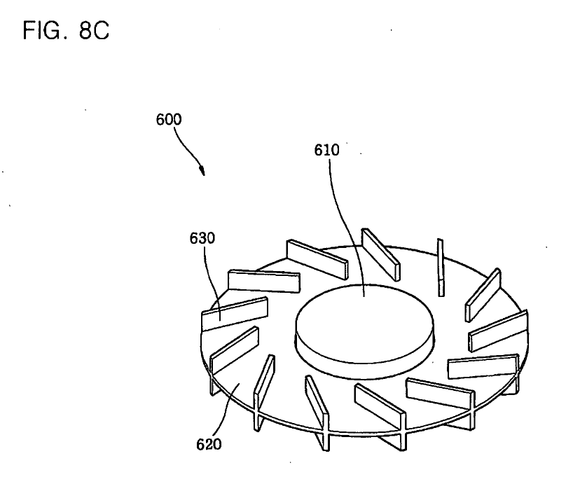

FIG. 8A through 8C are perspective views of centrifugal fans according to third through fifth embodiments of the invention.

The centrifugal fans according to the third through fifth embodiments of the invention will be described in reference to FIGS. 8A through 8C and about differences thereof in comparison with the first and second embodiments.

FIG. 8A is the perspective view of the centrifugal fan according to the third embodiment of the invention. In FIG. 8A, blades 430 of a centrifugal fan 400 externally contact by inner ends with a surface of a hub 410 and are arranged by outer ends beyond a disk 420 in comparison with the first embodiments.

Further, blades 430 of a centrifugal fan 400 are inclined at a certain angle about a line extended from a radius of the disk 420 in comparison with the second embodiments.

FIG. 8B is the perspective view of the centrifugal fan according to the fourth embodiment of the invention. In FIG. 8B, blades 530 of a centrifugal fan 500 externally contact by inner ends with a surface of a hub 510 and by outer ends with an outer periphery of a disk 520 in comparison with the first embodiments.

Further, blades 530 of a centrifugal fan 500 are inclined at a certain angle about a line extended from a radius of the disk 520 in comparison with the second embodiments.

FIG. 8C is the perspective view of the centrifugal fan according to the fifth embodiment of the invention. In FIG. 8C, blades 630 of a centrifugal fan 600 are arranged by inner ends between outer and inner peripheries of a disk 620 and externally contact by outer ends with an outer periphery of a disk 620 in comparison with the first embodiments.

Further, blades 630 of a centrifugal fan 600 are inclined at a certain angle about a line extended from a radius of the disk 620 in comparison with the second embodiments.

### SIXTH THROUGH EIGHTH EMBODIMENTS

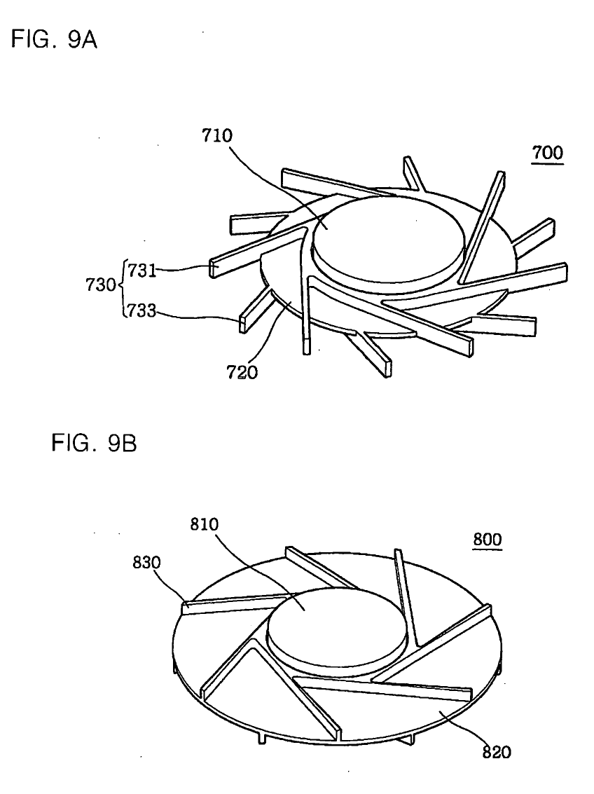

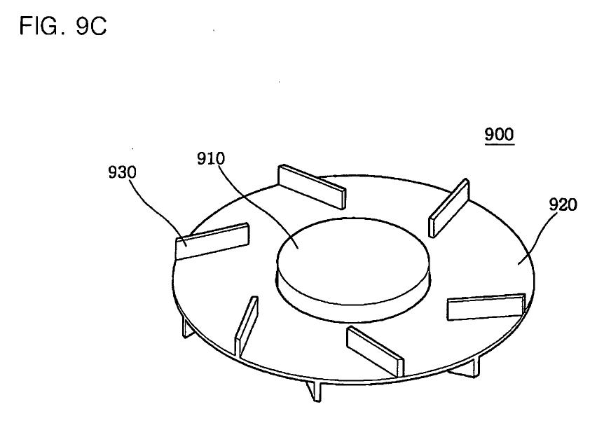

FIG. 9A through 9C are perspective views of centrifugal fans according to sixth through eighth embodiments of the invention.

The centrifugal fans according to the sixth through eighth embodiments of the invention will be described in reference to FIGS. 9A through 9C and about differences thereof in comparison with the first and second embodiments.

Unlike the first through fifth embodiments, the centrifugal fans according to the sixth through eighth embodiments of the invention have blades which are projected upward and downward respectively from a disk. Although the upwardly projected portions and the downwardly projected portions of the blades are identically shaped with each other, they are not symmetrically arranged. That is, the blades of the centrifugal fans are alternatingly arranged in upper and lower faces of the disk to a certain interval.

FIG. 9A is the perspective view of the centrifugal fan according to the sixth embodiment of the invention. In FIG. 9A, blades 730 of a centrifugal fan 700 include upper blades 731 and lower blades 733, and are arranged alternatingly in upper and lower faces of a disk 720 to an identical interval. That is, the upper blades 731 are arranged in the upper face of the disk 720 and are projected upward from the upper face of the disk 720, and inclined at a certain angle. And, lower blades 733 are arranged in the lower face of the disk 720 and are projected downward from the lower face of the disk 720, and inclined at a certain angle. The blades 730 also externally contact by inner ends with a hub 710 and are arranged by outer ends beyond the disk 720.

FIG. 9B is the perspective view of the centrifugal fan according to the seventh embodiment of the invention. In FIG. 9B, blades 830 of a centrifugal fan 800 include upper blades and lower blades, and are arranged alternatingly in upper and lower faces of a disk 820 to an identical interval. That is, the upper blades are arranged in the upper face of the disk 820 and are inclined at a certain angle upward from the upper face of the disk 820. And, lower blades are arranged in the lower face of the disk 820 and are inclined at a certain angle downward from the lower face of the disk 820. The blades 830 also externally contact by inner ends with a hub 810 and by outer ends with an outer periphery of the disk 820.

FIG. 9C is the perspective view of the centrifugal fan according to the eighth embodiment of the invention. In FIG. 9C, blades 930 of a centrifugal fan 900 include upper blades and lower blades, and are arranged alternatingly in upper and lower faces of a disk 920 to an identical interval. That is, the upper blades are arranged in the upper face of the disk 920 and are inclined at a certain angle upward from the upper face of the disk 920. And, lower blades are arranged in the lower face of the disk 920 and are inclined at a certain angle downward from the lower face of the disk 920.

Further, the blades 930 are arranged by inner ends between outer and inner peripheries of a disk 920 and externally contact by outer ends with the outer periphery of the disk 920.

In the centrifugal fan according to any of the first through eight embodiments of the invention, the hub, the disk and the blades may be integrally provided. Alternatively, the hub, the disk and the blades may be separately provided and then integrally coupled together.

Industrial Applicability

According to the centrifugal fan and the cooling apparatus using the same of the invention as set forth above, the disk is provided between the blades and the hub so that fluid is sucked to the both faces of the disk and then discharged toward the blades. That is, interference between sucked fluid is minimized to restrain creation of turbulence flow, thereby reducing noise and improving efficiency.

Also the inner ends of the blades of the centrifugal fan are arranged in the inner portion of the disk to relatively shorten the chord length of the blades, resultantly reducing tonal noise owing to BPF and thermal deformation of the blades.

Furthermore, since the magnitude of the disk is adjusted, the number of the blades is not restricted and the centrifugal fan of the invention and the cooling apparatus mounting the centrifugal fan therein can be applied to computers by restructuring the frame and the cover of the cooling apparatus.

Although the preferred embodiments of the present invention have been disclosed for illustrative purposes, those skilled in the art will appreciate that various modifications, additions and substitutions can be made without departing from the scope and spirit of the invention as disclosed in the accompanying claims.

1. A double suction centrifugal fan comprising:
a cylindrical hub having an opening in one face, and a motor is received in the opening;
a disk arranged in an outer periphery of the hub; and
a plurality of blades regularly arranged in the disk.

2. A double suction centrifugal fan set forth in claim 1, wherein the blades are radially-arranged and the blades have inner ends placed between inner and outer peripheries of the disk and outer ends placed beyond the disk.

3. A double suction centrifugal fan set forth in claim 1, wherein the inner ends of the blades externally contact with an outer periphery of the hub.

4. A double suction centrifugal fan set forth in claim 1, wherein the outer ends of the blades internally contact with an outer periphery of the disk.

5. A double suction centrifugal fan set forth in claim 1, wherein the inner ends of the blades externally contact with an outer periphery of the hub and the outer ends of the blades internally contact with an outer periphery of the disk.

6. A double suction centrifugal fan set forth in claim 1, wherein the blades of the centrifugal fan include
upper blades which are arranged in the upper face of the disk and are projected upward from the upper face of the disk, and inclined at a certain angle, and
lower blades which are arranged in the lower face of the disk and are projected downward from the lower face of the disk, and inclined at a certain angle, and
wherein the upper blades and the lower blades are arranged with a same interval, or a predetermined interval.

7. A double suction centrifugal fan set forth in claim 1, wherein at least some portion of the blades overlaps the disk.

8. A double suction centrifugal fan set forth in claim 1, wherein the hub, the disk and the blades are integrally injection molded.

9. A double suction centrifugal fan set forth in claim 1, wherein the hub, the disk and the blades are separately molded and integrally coupled together.

10. A cooling apparatus for a computer comprising:
a frame installed within a computer mainframe and having openings in a top and a lateral portion and a frame inlet in an underside;
a cover coupled to the upper opening of the frame and having a cover inlet which is concentric with the frame inlet and has a diameter similar to a diameter of the frame inlet;
a plurality of cooling fins arranged in the lateral opening of the frame;
a centrifugal fan including a cylindrical hub, a disk arranged in an outer periphery of the hub and a plurality of blades regularly arranged in the disk and for sucking fluid into the frame inlet and the cover inlet and discharging fluid toward the cooling fins; and
a motor for rotating the centrifugal fan.

11. A cooling apparatus for a computer set forth in claim 10, wherein the hub has an opening in one face

12. A cooling apparatus for a computer set forth in claim 10, wherein the blades are radially arranged from the center of the hub to face to the outside from the inside of the disk, and have inner ends placed between inner and outer peripheries of the disk and outer peripheries placed beyond the disk.

13. A cooling apparatus for a computer set forth in claim 10, wherein the inner ends of the blades externally contact with an outer periphery of the hub.

14. A cooling apparatus for a computer set forth in claim 10, wherein the outer ends of the blades internally contact with an outer periphery of the disk.

15. A cooling apparatus for a computer set forth in claim 10, wherein the inner ends of the blades externally contact with an outer periphery of the hub and the outer ends of the blades internally contact with an outer periphery of the disk.

16. A cooling apparatus for a computer set forth in claim 10, wherein the blades of the centrifugal fan include
upper blades which are arranged in the upper face of the disk and are projected upward from the upper face of the disk, and inclined at a certain angle, and
lower blades which are arranged in the lower face of the disk and are projected downward from the lower face of the disk, and inclined at a certain angle, and
wherein the upper blades and the lower blades are arranged with a same interval, or a predetermined interval.

17. A cooling apparatus for a computer set forth in claim 10, wherein the disk and the blades are arranged between inner and outer peripheries of the frame inlet, and the number of the blades is 36 to 64.

18. A cooling apparatus for a computer set forth in claim 10, wherein the hub, the disk and the blades are integrally injection molded.

19. A cooling apparatus for a computer set forth in claim 10, wherein the hub, the disk and the blades are separately molded and integrally coupled together.

20. A double suction centrifugal fan comprising:
a cylindrical hub;
a disk arranged in an outer periphery of the hub;
a plurality of blades regularly arranged in the disk; and
a turbulence preventing portion formed between double suction directions.

21. A cooling apparatus for a computer set forth in claim 20, wherein the hub has an opening in one face

22. A double suction centrifugal fan set forth in claim 20, wherein the turbulence preventing portion is the disk.

23. A double suction centrifugal fan set forth in claim 20, wherein the turbulence preventing portion is a portion of the disk formed in the suction region of the fan.

24. A double suction centrifugal fan set forth in claim 20, wherein the blades are provided to number 12 through 24.

25. A double suction centrifugal fan set forth in claim 20, wherein the turbulence preventing portion is blades which is interposed in the upward and downward of the disk.

26. A cooling apparatus for computer comprising double suction centrifugal fan, wherein the centrifugal fan has a cylindrical hub, a disk arranged in an outer periphery of the hub, and a plurality of blades regularly arranged in the disk.

27. A cooling apparatus for a computer set forth in claim 26, wherein the hub has an opening in one face

28. A cooling apparatus for computer comprising double suction centrifugal fan set forth in claim 26, wherein the blades are radially arranged and the blades have inner ends placed between inner and outer peripheries of the disk and outer ends placed beyond the disk.

29. A cooling apparatus for computer comprising double suction centrifugal fan set forth in claim 26, wherein the inner ends of the blades externally contact with an outer periphery of the hub.

30. A cooling apparatus for computer comprising double suction centrifugal fan set forth in claim 26, wherein the outer ends of the blades internally contact with an outer periphery of the disk.

31. A cooling apparatus for computer comprising double suction centrifugal fan set forth in claim 26, wherein the inner ends of the blades externally contact with an outer periphery of the hub and the outer ends of the blades internally contact with an outer periphery of the disk.

32. A cooling apparatus for computer comprising double suction centrifugal fan set forth in claim 26, wherein the blades of the centrifugal fan include
upper blades which are arranged in the upper face of the disk and are projected upward from the upper face of the disk, and inclined at a certain angle, and
lower blades which are arranged in the lower face of the disk and are projected downward from the lower face of the disk, and inclined at a certain angle, and
wherein the upper blades and the lower blades are arranged with a same interval, or a predetermined interval.

33. A cooling apparatus for computer comprising double suction centrifugal fan set forth in claim 26, wherein at least some portion of the blades overlaps the disk.

34. A cooling apparatus for computer comprising double suction centrifugal fan set forth in claim 26, wherein the hub, the disk and the blades are integrally injection molded.

35. A cooling apparatus for computer comprising double suction centrifugal fan set forth in claim 26, wherein the hub, the disk and the blades are separately molded and integrally coupled together.
